(19) United States
(12) Patent Application Publication
(10) Pub. No.: US 2008/0174320 A1
(43) Pub. Date: Jul. 24, 2008

(54) PARTIAL DISCHARGE SENSOR AND PARTIAL DISCHARGE MONITORING SYSTEM UTILIZING CURRENT SENSORS

(76) Inventors: JAMES E. SMITH, Pittsburgh, PA (US); JOE M. KELLIS, Weaverville, NC (US); ALFRED L. RANDALL, Horse Shoe, NC (US)

Correspondence Address: Martin J. Moran;Eaton Electrical, Inc., Technology & Quality Center, 170 Industry Drive, RIDC Park West, Pittsburgh, PA, 15275-1032, US

(21) Appl. No.: 11/626,465

(22) Filed: Jan. 24, 2007

(51) Int. Cl. G01R 31/08

(52) U.S. Cl. 324/551

(57) ABSTRACT

A partial discharge sensor includes a first current transformer having an opening. A conductive shield is disposed within the opening of and proximate to the first current sensor. The conductive shield has an opening. The concentric openings of the first current sensor and the conductive shield are structured to receive a first medium voltage power conductor. A second conductor is electrically connected to the conductive shield. The second conductor is structured to be electrically connected to ground. A second sensor cooperates with the second conductor and is structured to sense signals associated with partial discharge activity. An electronic monitoring circuit receives the output of the second sensor. The electronic monitoring circuit is structured to provide on-line monitoring of a partial discharge occurring within the first medium voltage power conductor.

### BACKGROUND OF THE INVENTION

1. Field of the Invention

This invention pertains generally to partial discharge technology and, more particularly, to on-line sensing of partial discharge utilizing conductive shields, such as insulator stress shields, as capacitive sensing devices.

2. Background Information

In medium voltage switchgear and medium voltage motor starter systems operating at about 5 kV and above, the mechanical failure of an insulation system due to partial discharge is a major problem. The result of the insulation system failure is an electrical fault, which causes structural damage and, potentially, bodily injury.

There are four known ways to detect the deterioration of a medium voltage insulation system. First of all, the medium voltage power system is shut down for inspection, traditional electrical testing and replacement of any degraded components. This procedure is conducted during routine maintenance.

Second, the medium voltage power system is shut down for off-line partial discharge testing, locating partial discharge sources and replacement of any damaged components.

Third, a sensor is inserted in the return ground path of a current transformer circuit. System noise is monitored on-line and readings are compared at repetitive (e.g., without limitation, periodic) time intervals. When changes of these readings indicate deterioration of the medium voltage insulation system, a shut down is scheduled and the problem is corrected before a failure occurs.

Fourth, a condenser bushing with embedded stress shields is employed to monitor system noise on-line. For example, suitable sensors are embedded in standoff insulators. Again, the readings are compared at repetitive time intervals, and when changes of the readings indicate deterioration, a shut down of the medium voltage power system is scheduled and the problem is corrected before a failure occurs. See, for example, U.S. Pat. Nos. 6,433,557; 6,489,782; and 6,504,382, which are incorporated by reference herein.

One problem with the latter approach is the relatively large size of the sensors, which is problematic in certain medium voltage power systems, such as, for example and without limitation, a medium voltage control motor starter.

Accordingly, there is room for improvement in partial discharge sensors.

There is also room for improvement in partial discharge monitoring systems.

### SUMMARY OF THE INVENTION

These needs and others are met by embodiments of the invention, which employ a number of grounded conductive shields within a corresponding number of current transformers to monitor partial discharge. In this manner, no significant additional space is required to insert the number of conductive shields in a medium voltage power system.

In accordance with one aspect of the invention, a partial discharge sensor comprises: a first current sensor having an opening; a conductive shield disposed within the opening of and proximate to the first current sensor, the conductive shield having an opening, the opening of the first current sensor and the opening of the conductive shield being structured to receive a first medium voltage power conductor; a second conductor electrically connected to the conductive shield, the second conductor being structured to be electrically connected to ground; and a second sensor cooperating with the second conductor, the second sensor being structured to sense signals associated with partial discharge activity.

The conductive shield may comprise a cylindrical-shaped conductor and a third conductor, the third conductor being electrically connected to the cylindrical-shaped conductor and being structured to be electrically connected to another conductive shield.

The first current sensor may include an insulator that engages the conductive shield.

As another aspect of the invention, a partial discharge sensor comprises: a housing; a plurality of first current sensors, each of the first current sensors having a first opening; a plurality of conductive shields, each of the conductive shields being disposed within the first opening of and proximate to a corresponding one of the first current sensors, such each of the conductive shields having a second opening, the first opening of the corresponding one of the first current sensors and the second opening of such each of the conductive shields being structured to receive a first medium voltage power conductor; a plurality of second conductors, each one of a number of the second conductors being electrically connected to a corresponding pair of the conductive shields, one of the second conductors being structured to be electrically connected to ground; and a second sensor cooperating with the one of the second conductors, the second sensor being structured to sense signals associated with partial discharge activity.

The housing may comprise an insulator structured to insulate the first current sensors and the conductive shields from each other.

Each of the first current sensors may have a cylindrical shape with the first opening; each of the conductive shields may have a cylindrical shape with the second opening; and the second opening of such each of the conductive shields may be concentric with the first opening of a corresponding one of the first current sensors.

Each of the first current sensors may include an insulator that engages a corresponding one of the conductive shields.

As another aspect of the invention, a partial discharge monitoring system comprises: a partial discharge sensor comprising: a first current sensor having an opening, a conductive shield disposed within the opening of and proximate to the first current sensor, the conductive shield having an opening, the opening of the first current sensor and the opening of the conductive shield being structured to receive a first medium voltage power conductor, second conductor electrically connected to the conductive shield, the second conductor being structured to be electrically connected to ground, and a second sensor cooperating with the second conductor, the second sensor comprising an output having signals associated with partial discharge activity; and an electronic monitoring circuit receiving the output of the second sensor, the electronic monitoring circuit being structured to provide on-line monitoring of a partial discharge occurring within the first medium voltage power conductor.

As another aspect of the invention, a current sensor assembly comprises: a current sensor having a first opening; a conductive shield disposed within the first opening and being proximate to the current sensor, the conductive shield having a second opening; a housing having a third opening disposed within the first and second openings, the housing the current sensor and the conductive shield, the first opening of the current sensor, the second opening of the conductive shield and the third opening of the housing being structured to receive a first medium voltage power conductor; and a second conductor electrically connected to the conductive shield, the second conductor being structured to be electrically connected to ground.

The current sensor may have a generally cylindrical shape with the first opening; the conductive shield may have a generally cylindrical shape with the second opening; the third opening of the housing may have a generally cylindrical shape; and the first, second and third openings may be concentric.

The housing may comprise an insulator disposed between the third opening and the conductive shield, and an insulator disposed between the conductive shield and the current sensor.

As another aspect of the invention, a medium voltage current sensor assembly comprises: a current sensor having a first opening; a conductive shield disposed within the first opening and being proximate to the current sensor, the conductive shield having a second opening; a first medium voltage power conductor disposed within the first opening of the current sensor and the second opening of the conductive shield, the first medium voltage power conductor comprising a first end, a second end and an intermediate portion between the first and second ends; a housing housing the current sensor, the conductive shield and the intermediate portion of the first medium voltage power conductor; and a second conductor electrically connected to the conductive shield, the second conductor being structured to be electrically connected to ground.

### BRIEF DESCRIPTION OF THE DRAWINGS

A full understanding of the invention can be gained from the following description of the preferred embodiments when read in conjunction with the accompanying drawings in which:

FIG. 1 is an isometric view of a partial discharge sensor in accordance with an embodiment of the invention with a portion of the housing broken away to show internal structures.

FIG. 2 is a block diagram of a partial discharge monitoring system in accordance with another embodiment of the invention.

FIG. 3 is an isometric view of a partial discharge sensor in accordance with another embodiment of the invention.

FIG. 4 is a cross-section along lines 4-4 of FIG. 3.

FIG. 5 is an isometric view of a partial discharge sensor in accordance with another embodiment of the invention.

FIG. 6 is a cross-section along lines 6-6 of FIG. 5.

### DESCRIPTION OF THE PREFERRED EMBODIMENTS

As employed herein, the term “number” shall mean one or an integer greater than one (i.e., a plurality).

As employed herein, the term “current sensor” shall mean a low voltage or medium voltage current transformer or any suitable sensor for sensing current flowing through a medium voltage power conductor.

As employed herein, the term “stress shield” shall mean a conductive shield employed in sensing capacitance between an insulated power conductor and such conductive shield. Preferably, the stress shield has a voltage at or suitably close to ground potential.

As employed herein, the term “proximate” shall mean that one component is very near, or is immediately preceding or following another component, with only a suitably thin insulator or a suitably small air gap therebetween. For example, the disclosed conductive shield is disposed within the opening of and is proximate to the disclosed low voltage or medium voltage current sensor with a suitable insulative gap (e.g., without limitation, about 0.01 inch; any suitably small gap) therebetween.

As employed herein, the term “low voltage” shall mean any voltage that is less than about 690 V_{RMS}.

As employed herein, the term “medium voltage” shall mean any voltage in the range from about 1 kV_{RMS} to about 38 kV_{RMS}.

The invention is described in association with single-phase and three-phase partial discharge sensing in connection with a number of low voltage or medium voltage current transformers, although the invention is applicable to a wide range of partial discharge sensing associated with any number of low voltage or medium voltage current sensors.

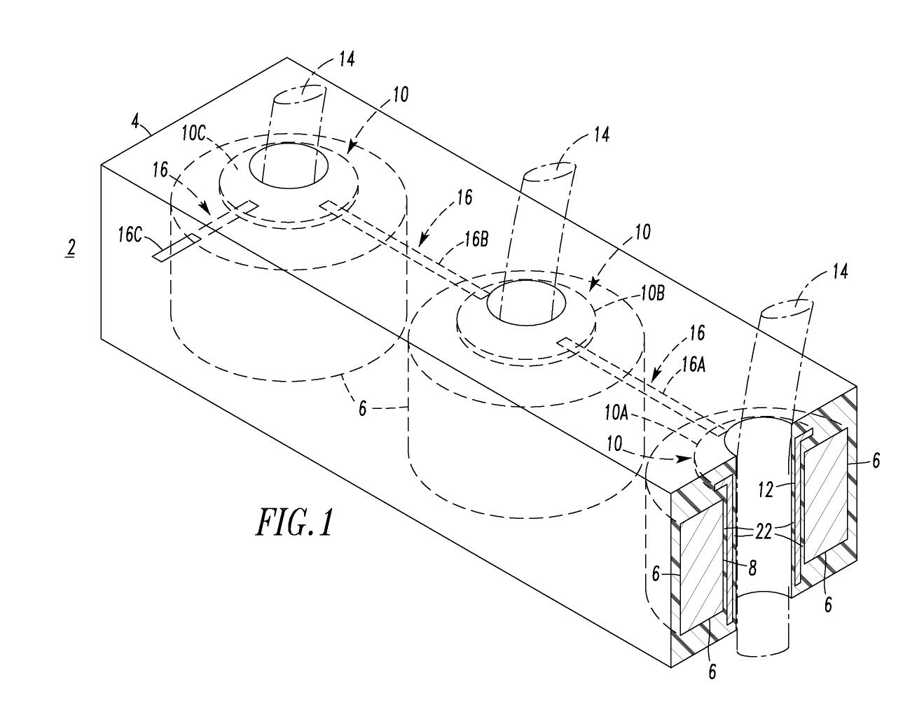

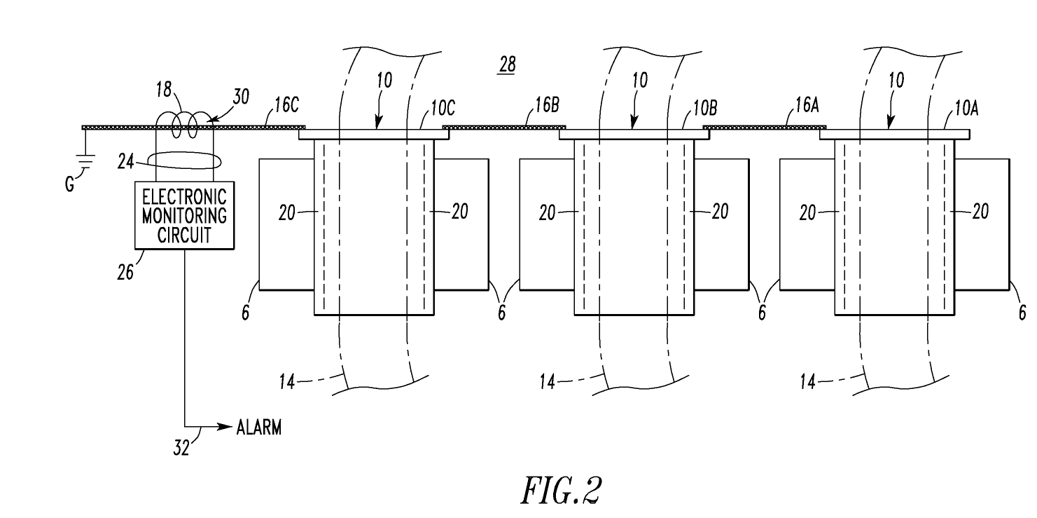

Referring to FIG. 1, a partial discharge sensor 2 includes a housing 4, a plurality of first (e.g., without limitation, low voltage) current sensors 6 having first openings 8 (only one first opening 8 is shown), and a plurality of conductive shields 10 having second openings 12 (only one second opening 12 is shown). Each of the conductive shields 10 is disposed within a corresponding one of the first openings 8 and is proximate to a corresponding one of the first current sensors 6. Each pair of the first and second openings 8,12 is structured to receive a first medium voltage power conductor 14 (shown in phantom line drawing). The partial discharge sensor 2 also includes a plurality of second conductors 16. Each one of a number of the second conductors 16 is electrically connected to a corresponding pair of the conductive shields 10. For example, as shown in FIG. 1, each of two conductors 16A,16B of the three second conductors 16 is electrically connected to a corresponding pair 10A and 10B or 10B and 10C of the conductive shields 10. One conductor 16C of the second conductors 16 is structured to be electrically connected to ground G (FIG. 2). As shown in FIG. 2, a second sensor 18 cooperates with the conductor 16C and is structured to sense signals associated with partial discharge activity.

### Example 1

The conductive shields 10 have a voltage that is about ground potential.

### Example 2

The second conductors 16 are made of a braided conductor, a copper mesh or any suitable conductor. The second conductors 16 are preferably brazed to the conductive shield 10.

### Example 3

The conductive shield 10 is a conductive mesh made of copper, aluminum, brass or any suitable conductor.

### Example 4

The conductive shield 10C includes a cylindrical-shaped conductor 20 (FIG. 2) and two of the second conductors 16. For example, one conductor 16C of the second conductors 16 is structured to be electrically connected to ground G and another (third) conductor 16B is structured to be electrically connected to another conductive shield 10B as shown in FIG. 2.

### Example 5

The first current sensor 6 has a cylindrical shape, and the conductive shield 10 has a shape corresponding to the cylindrical shape. The cylindrical shape of the first current sensor 6 forms the first opening 8, the cylindrical shape of the conductive shield 10 forms the second opening 12, and the second opening 12 of the conductive shield 10 is concentric with the first opening 8.

### Example 6

The first current sensor 6 includes an insulator 22 that engages the conductive shield 10.

### Example 7

The housing 4 includes an insulator 22 structured to insulate the first current sensors 6 and the conductive shields 10 from each other.

### Example 8

The insulator 22 is selected from the group consisting of epoxy, polyurethane, rubber and neoprene, although any suitable insulator may be employed.

### Example 9

In order to monitor the deterioration of the insulation system within a medium voltage power system, such as, without limitation, medium voltage switchgear or a medium voltage control system, a ground plane is employed. In accordance with an important aspect of the invention, the conductive shield 10, the voltage of which is near ground potential, is grounded after the conductor 16C, which is electrically connected to the conductive shield 10, passes through the partial discharge (PD) sensor 18 to ground G, as shown in FIG. 2. The signal 24 from the PD sensor 18 is input by an electronic monitoring circuit 26. This permits the on-line monitoring of a partial discharge occurring within the energized medium voltage power system. For example, it is possible to monitor any number of phases (e.g., without limitation, all three phases as a group; a single phase; any suitable number of phases).

Continuing to refer to FIG. 2, a partial discharge monitoring system 28 includes the partial discharge sensor 2 of FIG. 1 and the electronic monitoring circuit 26 that receives the output of the PD sensor 18. The PD sensor 18 has an opening 30 and the second conductor 16C passes through that opening 30. The electronic monitoring circuit 26 is structured to provide on-line monitoring of a partial discharge occurring within any one, some or all of the first medium voltage power conductors 14.

### Example 10

The electronic monitoring circuit 26 is preferably structured to monitor changes in partial discharge intensity (e.g., the energy dissipation (mW) caused by partial discharges) and changes in partial discharge (e.g., the voltage drop (mV) caused by partial discharges). For example, the monitoring circuit 26 includes suitable resistors (not shown) to measure both partial discharge and partial discharge intensity. As a non-limiting example, for a 15 kV_{RMS} medium voltage power cable (not shown), a partial discharge intensity of 3 mW produces a warning output (not shown) and a partial discharge intensity of 10 mW produces an alarm 32.

### Example 11

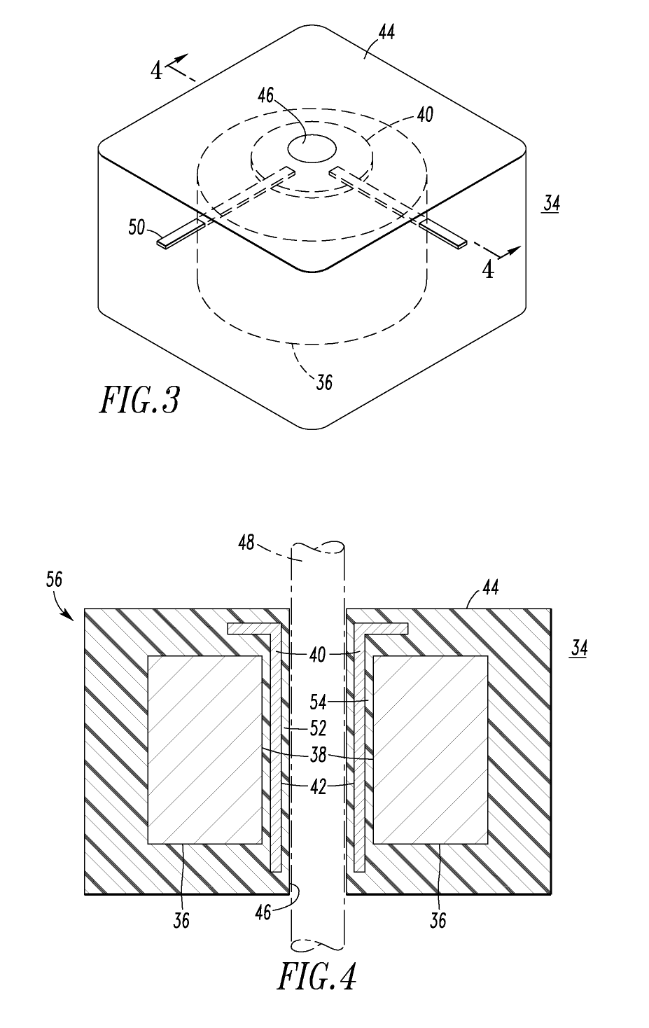

Referring to FIGS. 3 and 4, a current sensor assembly 34 includes a first (e.g., without limitation, low voltage) current sensor 36 having a first opening 38, a conductive shield 40 having a second opening 42 disposed within the first opening 38 and being proximate to the first current sensor 36, and a housing 44 having a third opening 46 disposed within the first and second openings 38,42. The housing 44 houses the first current sensor 36 and the conductive shield 40. The first opening 38, the second opening 42 and the third opening 46 are structured to receive a first medium voltage power conductor 48. The first medium voltage power conductor 48 includes an outer insulator (not shown) and may fill or substantially fill the third opening 46. A second conductor 50 (FIG. 3) is electrically connected to the conductive shield 40 and is structured to be electrically connected to ground (not shown) (see, for example, ground G of FIG. 2).

### Example 12

The first current sensor 36 has a generally cylindrical shape with the first opening 38. The conductive shield 40 has a generally cylindrical shape with the second opening 42. The third opening 46 of the housing 44 has a generally cylindrical shape. The first, second and third openings 38,42,46 are concentric.

### Example 13

The housing 44 includes an insulator 52 disposed between the third opening 46 and the conductive shield 40, and an insulator 54 disposed between the conductive shield 40 and the first current sensor 36.

### Example 14

A partial discharge sensor 56 includes the current sensor assembly 34 of FIG. 3 and the PD sensor 18 of FIG. 2. As was discussed above, the PD sensor 18 cooperates with the conductor 16C (FIGS. 1 and 2) or 50 (FIG. 3) and is structured to sense signals associated with partial discharge activity.

### Example 15

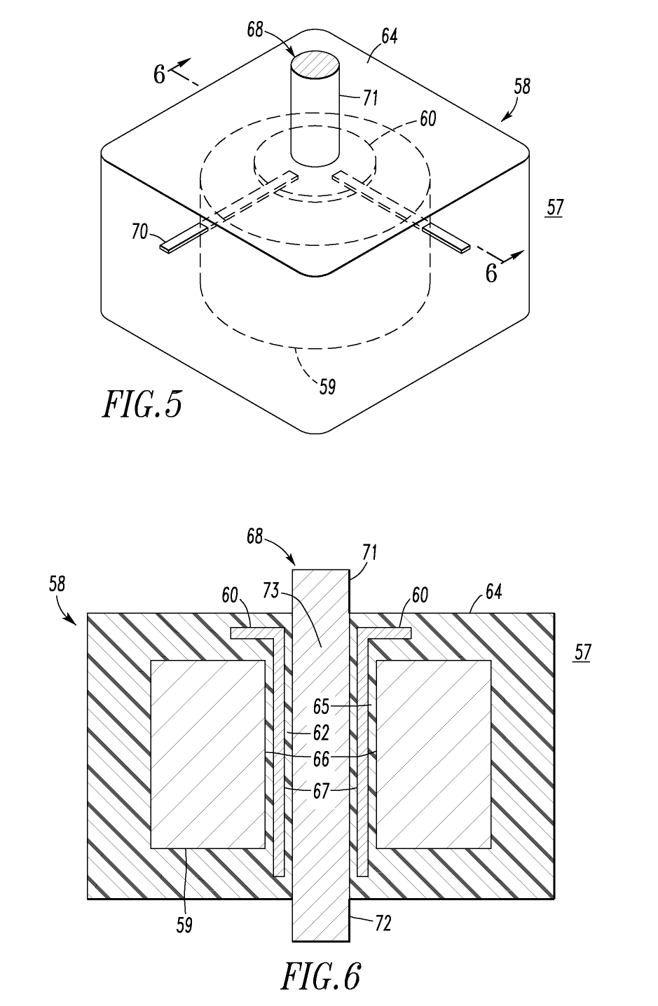

FIGS. 5 and 6 show a medium voltage current sensor assembly 57 including a first current sensor 59 having a first opening 66, a conductive shield 60 having a second opening 67 disposed within the first opening 66 and being proximate to the first current sensor 59. A housing 64 houses the first current sensor 59, the conductive shield 60 and an intermediate portion 73 of a first medium voltage power conductor 68, which has first and second ends 71,72 (e.g., terminals) protruding from the housing 64. The first opening 66 and the second opening 67 are structured to receive the first medium voltage power conductor 68 (e.g., without limitation, medium voltage bus bar). The first medium voltage power conductor 68 is disposed within the first and second openings 66,67 and is proximate to the first current sensor 59. A second conductor 70 (FIG. 5) is electrically connected to the conductive shield 60 and is structured to be electrically connected to ground (not shown) (see, for example, ground G of FIG. 2). Although a single phase is shown, sensor assemblies for two or more phases may be employed.

### Example 16

The first current sensor 59 has a generally cylindrical shape with the first opening 66. The conductive shield 60 has a generally cylindrical shape with the second opening 67. The first and second openings 66,67 are concentric.

### Example 17

The housing 64 includes an insulator 62 disposed between the conductive shield 60 and the first medium voltage power conductor 68, and an insulator 65 disposed between the conductive shield 60 and the first current sensor 59.

### Example 18

A partial discharge sensor 58 includes the current sensor assembly 57 of FIG. 5 and the PD sensor 18 of FIG. 2. As was discussed above, the PD sensor 18 cooperates with the conductor 16C (FIGS. 1 and 2) or 70 (FIG. 5) and is structured to sense signals associated with partial discharge activity.

### Example 19

The disclosed conductive shields 10, 40 and 60 are suitable for applications where a number of the current sensors 6, 36 and 59, such as current transformers, are employed, for example, for metering or protective relaying of a medium voltage power system.

### Example 20

The disclosed conductive shields 10 and 40 may be added to the exterior of existing low voltage single-phase current sensors 6 and 36, or may be embedded in insulation (e.g., without limitation, plastic) or be suitably mounted inside of such low voltage single-phase current sensors. The disclosed conductive shield 60 can be suitably embedded inside of the medium voltage single phase current sensor 59. Hence, the conductive shields 10, 40 and 60 are near ground potential at or about the respective current sensors 6, 36 and 59.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

What is claimed is:

1. A partial discharge sensor comprising:
a first current sensor having an opening;
a conductive shield disposed within the opening of and proximate to said first current sensor, said conductive shield having an opening, the opening of said first current sensor and the opening of said conductive shield being structured to receive a first medium voltage power conductor;
a second conductor electrically connected to said conductive shield, said second conductor being structured to be electrically connected to ground; and
a second sensor cooperating with said second conductor, said second sensor being structured to sense signals associated with partial discharge activity.

2. The partial discharge sensor of claim 1 wherein said conductive shield has a voltage that is about ground potential.

3. The partial discharge sensor of claim 1 wherein said second sensor has an opening; and wherein said second conductor passes through the opening of said second sensor.

4. The partial discharge sensor of claim 1 wherein said second conductor is a braided conductor.

5. The partial discharge sensor of claim 1 wherein said second conductor is made of a copper mesh.

6. The partial discharge sensor of claim 1 wherein said conductive shield is a conductive mesh made of copper, aluminum or brass.

7. The partial discharge sensor of claim 1 wherein said conductive shield comprises a cylindrical-shaped conductor and a third conductor, said third conductor being electrically connected to said cylindrical-shaped conductor and being structured to be electrically connected to another conductive shield.

8. The partial discharge sensor of claim 1 wherein said first current sensor has a cylindrical shape; and wherein said conductive shield has a shape corresponding to said cylindrical shape.

9. The partial discharge sensor of claim 8 wherein said cylindrical shape forms the opening of said first current sensor; and wherein the opening of said conductive shield is concentric with the opening of said first current sensor.

10. The partial discharge sensor of claim 9 wherein said first current sensor includes an insulator that engages said conductive shield.

11. A partial discharge sensor comprising:
a housing;
a plurality of first current sensors, each of said first current sensors having a first opening;
a plurality of conductive shields, each of said conductive shields being disposed within the first opening of and proximate to a corresponding one of said first current sensors, said each of said conductive shields having a second opening, the first opening of said corresponding one of said first current sensors and the second opening of said each of said conductive shields being structured to receive a first medium voltage power conductor;
a plurality of second conductors, each one of a number of said second conductors being electrically connected to a corresponding pair of said conductive shields, one of said second conductors being structured to be electrically connected to ground; and
a second sensor cooperating with said one of said second conductors, said second sensor being structured to sense signals associated with partial discharge activity.

12. The partial discharge sensor of claim 11 wherein said housing comprises an insulator structured to insulate said first current sensors and said conductive shields from each other.

13. The partial discharge sensor of claim 12 wherein said insulator is selected from the group consisting of epoxy, polyurethane, rubber and neoprene.

14. The partial discharge sensor of claim 11 wherein each of said first current sensors has a cylindrical shape with the first opening; wherein each of said conductive shields has a cylindrical shape with the second opening; and wherein the second opening of said each of said conductive shields is concentric with the first opening of a corresponding one of said first current sensors.

15. The partial discharge sensor of claim 11 wherein said each of said first current sensors includes an insulator that engages a corresponding one of said conductive shields.

16. A partial discharge monitoring system comprising:
a partial discharge sensor comprising:
a first current sensor having an opening,
a conductive shield disposed within the opening of and proximate to said first current sensor, said conductive shield having an opening, the opening of said first current sensor and the opening of said conductive shield being structured to receive a first medium voltage power conductor,
a second conductor electrically connected to said conductive shield, said second conductor being structured to be electrically connected to ground, and
a second sensor cooperating with said second conductor, said second sensor comprising an output having signals associated with partial discharge activity; and
an electronic monitoring circuit receiving the output of said second sensor, said electronic monitoring circuit being structured to provide on-line monitoring of a partial discharge occurring within the first medium voltage power conductor.

17. The partial discharge monitoring system of claim 16 wherein said conductive shield has a voltage that is about ground potential.

18. The partial discharge monitoring system of claim 16 wherein said second sensor has an opening; and wherein said second conductor passes through the opening of said second sensor.

19. A current sensor assembly comprising:
a current sensor having a first opening;
a conductive shield disposed within the first opening and being proximate to said current sensor, said conductive shield having a second opening;
a housing having a third opening disposed within the first and second openings, said housing said current sensor and said conductive shield, the first opening of said current sensor, the second opening of said conductive shield and the third opening of said housing being structured to receive a first medium voltage power conductor; and
a second conductor electrically connected to said conductive shield, said second conductor being structured to be electrically connected to ground.

20. The current sensor assembly of claim 19 wherein said current sensor has a generally cylindrical shape with the first opening; wherein said conductive shield has a generally cylindrical shape with the second opening; wherein the third opening of said housing has a generally cylindrical shape; and wherein said first, second and third openings are concentric.

21. The current sensor assembly of claim 19 wherein said housing comprises an insulator disposed between said third opening and said conductive shield, and an insulator disposed between said conductive shield and said current sensor.

22. A medium voltage current sensor assembly comprising:
a current sensor having a first opening;
a conductive shield disposed within the first opening and being proximate to said current sensor, said conductive shield having a second opening;
a first medium voltage power conductor disposed within the first opening of said current sensor and the second opening of said conductive shield, said first medium voltage power conductor comprising a first end, a second end and an intermediate portion between the first and second ends;
a housing said current sensor, said conductive shield and the intermediate portion of said first medium voltage power conductor; and
a second conductor electrically connected to said conductive shield, said second conductor being structured to be electrically connected to ground.

23. The medium voltage current sensor assembly of claim 22 wherein said housing comprises an insulator disposed between said conductive shield and said first medium voltage power conductor, and an insulator disposed between said conductive shield and said current sensor.
